(19) United States
(12) Patent Application Publication
(10) Pub. No.: US 2006/0274585 A1
(43) Pub. Date: Dec. 7, 2006

(54) Memory device with row shifting for defective row repair

(76) Inventor: Chang Ho Jung, San Diego, CA (US)

Correspondence Address: QUALCOMM INCORPORATED, 5775 MOREHOUSE DR., SAN DIEGO, CA, 92121, US

(21) Appl. No.: 11/145,425

(22) Filed: Jun. 3, 2005

(51) Int. Cl. G11C 29/00

(52) U.S. Cl. 365/200

(57) ABSTRACT

A memory device includes N regular rows of memory cells, L redundant rows of memory cells, a shift circuit, and N word lines, where N>1 and L>1. Each word line is associated with a designated row and an alternate row that is L rows away from the designated row. The shift circuit receives the N word lines and couples each word line to either the designated row or the alternate row for that word line. If L is two, then the shift circuit couples even-numbered word lines to even-numbered rows and odd-numbered word lines to odd-numbered rows. The shift circuit may couple each word line to (1) the designated row if this row is non-defective and a preceding word line is not shifted down or (2) the alternate row otherwise.

### BACKGROUND

I. Field

The present disclosure relates generally to electronics, and more specifically to a memory device.

II. Background

Memory devices are commonly used in many electronics devices such as computers, wireless communication devices, personal digital assistants (PDAs), and so on. Continuous improvements in integrated circuit (IC) fabrication technology have resulted in higher operating speed and more processing power for many electronic devices. The improved speed and processing power enable the electronic devices to support more complicated applications, many of which require larger and faster memories.

The manufacturing process for memory devices is complex and challenging, especially as the number of memory cells increases and the size of the memory cells decreases. It is difficult to manufacture a memory device without any defective memory cell. Hence, some defective memory cells are typically present in any given manufactured memory device. For costs and other considerations, it is impractical to reject an entire memory device if only a few memory cells are actually defective. Thus, to improve production yields, redundant memory cells are typically fabricated on each memory device. During production and/or testing phase, the cells in the memory device are tested and cells identified as defective are replaced with redundant cells.

Various techniques may be used to replace defective memory cells with redundant cells. In one common technique, an address comparator is used to disable a defective row of memory cells and to enable a redundant row of memory cells. Unfortunately, the address comparator introduces additional delay that reduces the operating speed of the memory device.

There is therefore a need in the art for a memory device capable of replacing defective memory cells with little degradation in operating speed.

### SUMMARY

A memory device with row shifting for defective row repair is described herein. This memory device is capable of replacing defective rows of memory cells with little impact to operating speed.

In an embodiment, the memory device includes multiple (N) regular rows of memory cells, at least two (L) redundant rows of memory cells, and a shift circuit. Multiple (N) word lines are used to enable and disable N active rows among the N+L total rows of memory cells. Each word line Wₓ is associated with a designated row of memory cells (e.g., regular row x) and an alternate row of memory cells that is L rows away from the designated row.

The shift circuit receives the N word lines and couples each word line to either the designated row of memory cells or the alternate row of memory cells for that word line. For example, if L is two, then the shift circuit couples even-numbered word lines to even-numbered rows of memory cells and odd-numbered word lines to odd-numbered rows of memory cells. The shift circuit may couple each word line to (1) the designated row if this row is non-defective and if a preceding word line is not shifted down or (2) the alternate row otherwise. The detection for a defective row and the coupling of the word lines to non-defective rows may be performed in various manners, as described below.

The memory device described herein is capable of repairing up to L adjacent defective rows. The memory device may also be used for various types of memories and may be fabricated as a stand-alone memory IC or as an embedded memory.

Various aspects and embodiments of the invention are described in further detail below.

### BRIEF DESCRIPTION OF THE DRAWINGS

The features and nature of the present invention will become more apparent from the detailed description set forth below when taken in conjunction with the drawings in which like reference characters identify correspondingly throughout.

FIG. 1 shows a memory device with row shifting for defective row repair.

FIG. 2 shows an embodiment of a row shifter within the memory device.

FIG. 3 shows another embodiment of the row shifter.

FIG. 4 shows switches within the row shifter.

FIG. 5 shows a block diagram of a wireless device.

### DETAILED DESCRIPTION

The word “exemplary” is used herein to mean “serving as an example, instance, or illustration.” Any embodiment or design described herein as “exemplary” is not necessarily to be construed as preferred or advantageous over other embodiments or designs.

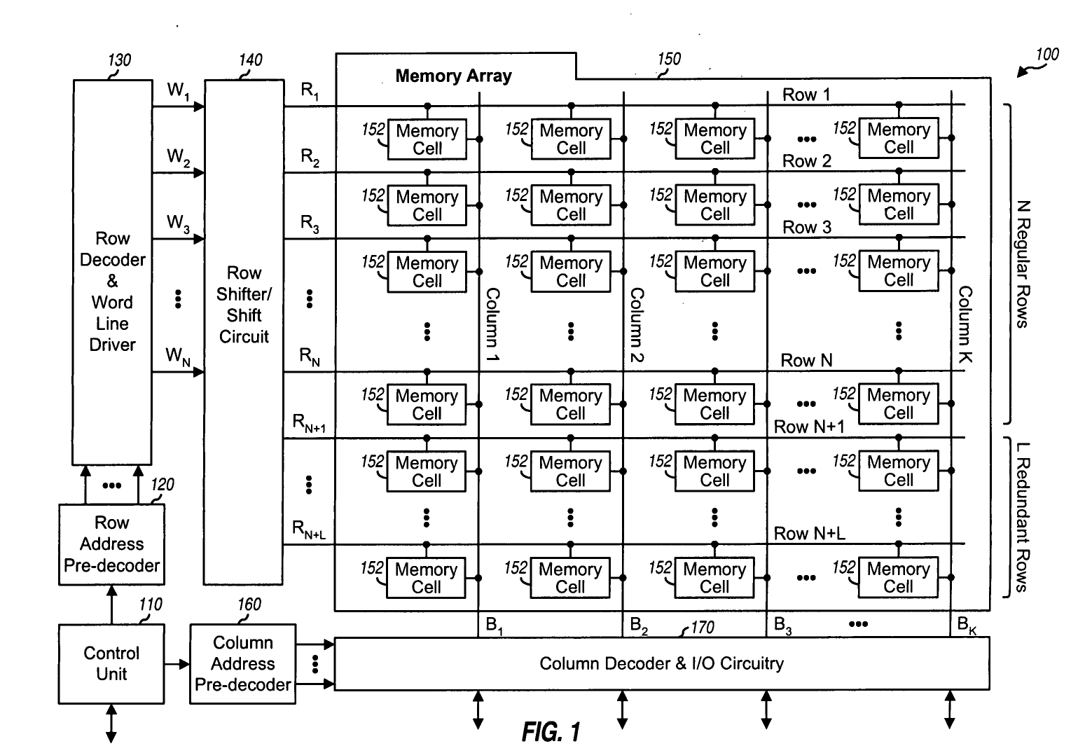

FIG. 1 shows a memory device 100 with row shifting for defective row repair. Memory device 100 includes a control unit 110, a row address pre-decoder 120, a row decoder and word line driver 130, a row shifter/shift circuit 140, a memory array 150, a column address pre-decoder 160, and a column decoder and input/output (I/O) circuitry 170.

Memory array 150 includes N regular rows of memory cells 152 and L redundant/spare rows of memory cells 152, where in general N>1 and L>1. For example, memory array 150 may include 256 (or 512) regular rows and two (or four) redundant rows. The N+L rows of memory cells are coupled to N+L row lines R₁ through R_{N+L}. Only N rows among the N+L total rows in memory array 150 are actually used and are called active rows. The remaining L rows are not used. The specific rows to use as the active rows are dependent on which rows are non-defective and which rows are defective. For example, regular rows 1 through N may be used as N active rows if all of these regular rows are non-defective. If any one of regular rows 1 through N is defective, then the N−1 non-defective regular rows plus one redundant row may be used as the N active rows. The L redundant rows may be used in place of up to L defective regular rows.

Each row within memory array 150 includes K memory cells, where K>1. The memory cells in the N+L rows are arranged into K columns. The K columns of memory cells are coupled to K bit lines B₁ through B_{K}.

One row line and one or more bit lines may be asserted at any given moment. The asserted row line enables all of the memory cells coupled to that row line. Each asserted bit line couples an enabled memory cell in the asserted row to I/O circuitry 170 so that the memory cell can be accessed, e.g., read from or written to.

Control unit 110 receives an address for a memory cell or a block of memory cells to be accessed and generates a row address for row address pre-decoder 120 and a column address for column address pre-decoder 160 based on the received address. Control unit 110 also generates internal clocks and command signals used to control the operation of memory device 100.

Row address pre-decoder 120 performs pre-decoding on the row address from control unit 120. For example, memory array 150 may include 256 rows, and each row may be identified by an 8-bit row address b₇b₆b₅b₄b₃b₂b₁b₀, where b₇ is the most significant bit and b₀ is the least significant bit. Pre-decoder 120 may organize the 8-bit row address into a 2-bit upper segment containing the two most significant bits b₇b₆, a 3-bit middle segment containing the next three most significant bits b₅b₄b₃, and a 3-bit lower segment containing the three least significant bits b₂b₁b₀. Pre-decoder 120 may then decode the 3-bit lower segment into eight pre-decoded lines d₇ through d₀, the 3-bit middle segment into another eight pre-decoded lines d₁₅ through d₈, and the 2-bit upper segment into four pre-decoded lines d₁₉ through d₁₆. Pre-decoder 120 would then provide the 20 pre-decoded lines d₀ through d₁₉ to row decoder 130. Pre-decoder 120 may also perform the pre-decoding in other manners.

Row decoder and word line driver 130 receives the pre-decoded lines for the row address, determines the proper word line to assert based on these pre-decoded lines, and drives the asserted word line so that the desired row of memory cells can be accessed. N word lines W₁ through W_{N} are provided for the N active rows in memory array 150, one word line for each active row. Row shifter 140 receives the N word lines W₁ through W_{N} and couples or maps these word lines to N row lines for the N active rows. Control unit 110, row address pre-decoder 120, and row decoder and word line driver 130 operate in the same manner regardless of which rows within memory array 150 are defective. The N word lines may be viewed as logical control lines for the N active rows. Row shifter 140 performs the mapping of the logical word lines to the physical row lines for the rows that are actually used. Row shifter 140 hides the details of the defective row replacement so that memory array 150 appears to function in the same manner to control unit 110, row address pre-decoder 120, and row decoder and word line driver 130 regardless of which rows, if any, are defective.

Column address pre-decoder 160 receives the column address from control unit and generates pre-decoded lines for the column address, e.g., in a manner similar to the manner described above for row address pre-decoder 120. Column decoder and I/O circuitry 170 receives the pre-decoded lines for the column address, determines the proper bit line(s) to assert based on the pre-decoded lines, and asserts these bit line(s) to enable access of the desired memory cells. I/O circuitry 170 includes various circuits such as amplifiers, buffers, comparators, and so on used for reading data from and writing data to the memory cells within memory array 150. For a data read operation, I/O circuitry 170 amplifies the signals on the asserted bit lines, detects the data values of the amplified signals (e.g., logic low or logic high), and provides output data via I/O lines. For a data write operation, I/O circuitry 170 receives input data via the I/O lines and drives the asserted bit lines to store the data in the enabled memory cells.

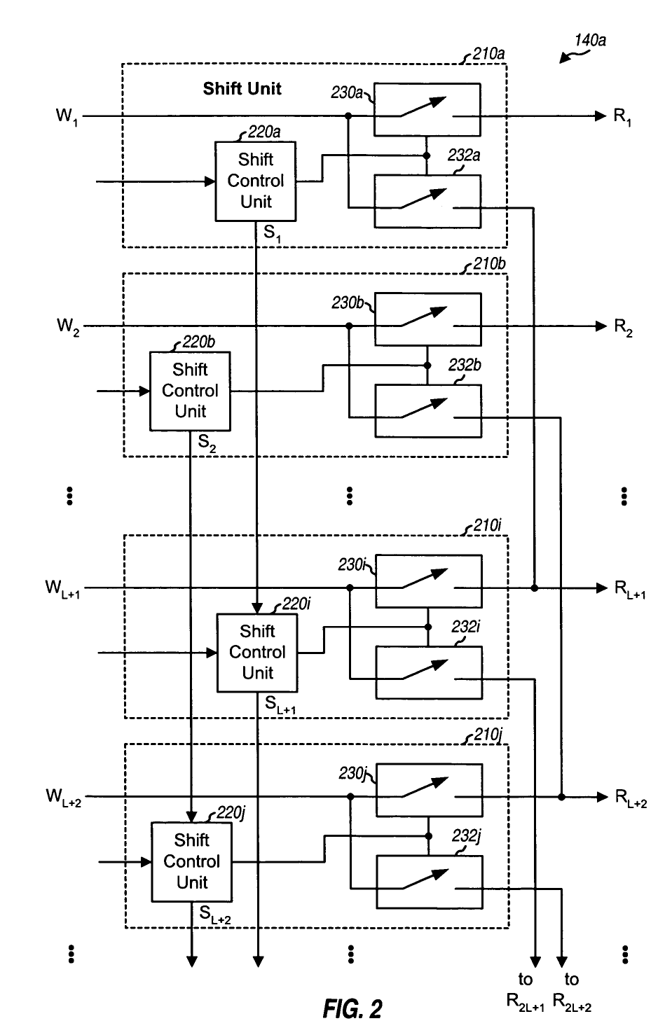

FIG. 2 shows a row shifter 140a, which is an embodiment of row shifter 140 within memory device 100 in FIG. 1. For this embodiment, row shifter 140a includes N shift units 210 for the N word lines. Each shift unit 210 couples to one word line and further to two row lines that are separated by L rows. Thus, shift unit 210a couples to the first word line W₁ and to row lines R₁ and R_{L+1}, shift unit 210b couples to the second word line W₂ and to row lines R₂ and R_{L+2}, and so on, and the last shift unit (not shown in FIG. 2) couples to the last word line W_{N} and to row lines R_{N} and R_{N+L}.

Each shift unit 210 includes a shift control unit 220 and two switches 230 and 232. Within shift unit 210a for the first word line W₁, switch 230a has one end coupled to word line W₁ and the other end coupled to row line R₁, and switch 232a has one end coupled to word line W₁ and the other end coupled to row line R_{L+1}. Shift control unit 220a receives an indication as to whether row 1 is defective and generates a control signal S₁ for switches 230a and 232a. If row 1 is not defective, then switch 230a is enabled and couples word line W₁ to row line R₁, and switch 232a is disabled. Conversely, if row 1 is defective, then switch 230a is disabled, and switch 232a is enabled and couples word line W₁ to row line R_{L+1}. The control signal S₁ may also be used as a 1-bit status that indicates whether word line W₁ is coupled to row line R₁ or R_{L+1}.

Shift unit 210 for each of word lines W₂ through W_{L} is coupled in the same manner as shift unit 210a for the first word line W₁. For word lines W₁ through W_{L}, the shift unit for each word line Wₓ (where x ∈ {1, . . . , L}) couples word line Wₓ to row line Rₓ if regular row x is not defective and to row line R_{L+x} if regular row x is defective.

Within shift unit 210i for word line W_{L+1}, shift control unit 220i receives an indication as to whether row L+1 is defective and the control signal S₁ from shift control unit 220a for word line W₁. Shift control unit 220i generates a control signal S_{L+1} for switches 230i and 232i based on the two inputs. If row L+1 is not defective and if word line W₁ is coupled to row line R₁, then switch 230i is enabled and couples word line W_{L+1} to row line R_{L+1}, and switch 232i is disabled. Conversely, if row L+1 is defective or if word line W₁ is coupled to row line R_{L+1}, then switch 230i is disabled, and switch 232i is enabled and couples word line W_{L+1} to row line R_{2L+1}.

Shift unit 210 for each of word lines W_{L+2} through W_{N} is coupled in the same manner as shift unit 210i for word line W_{L+1}. For word lines W_{L+1} through W_{N}, the shift unit for each word line W_{y} (where y Å {L+1, . . . , N}) couples word line W_{y} to row line R_{y} if regular row y is not defective and if word line W_{y-L} is not coupled to row line R_{y}. The shift unit couples word line WY to row line R_{y+L} if regular row y is defective or if word line W_{y-L} is coupled to row line R_{y}.

Each word line W_{z} (where z ∈ {1, . . . , N}) is thus associated with a designated row line R_{z} and an alternative row line R_{z+L}. For the embodiment shown in FIG. 2, each shift unit 210 couples its word line W_{z} to either the designated row line R_{z} or the alternate row line R_{z+L}. If a defective row is detected among the N regular row, then the word line for that defective row and all subsequent word lines that are an integer multiple of L row away from this word line are shifted down by L rows. For example, a defective row 3 will result in word lines W₃, W_{3+L}, W_{3+2L}, and so on to be shifted down by L rows and coupled to row lines R_{3+L}, R_{3+2L}, R_{3+3L}, and so on. This shift-by-L feature allows for repair of up to L adjacent defective rows. This repair capability is especially advantageous as IC geometry shrinks and manufacturing defects tend to cause localized row failures, so that multiple adjacent rows are more likely to be defective.

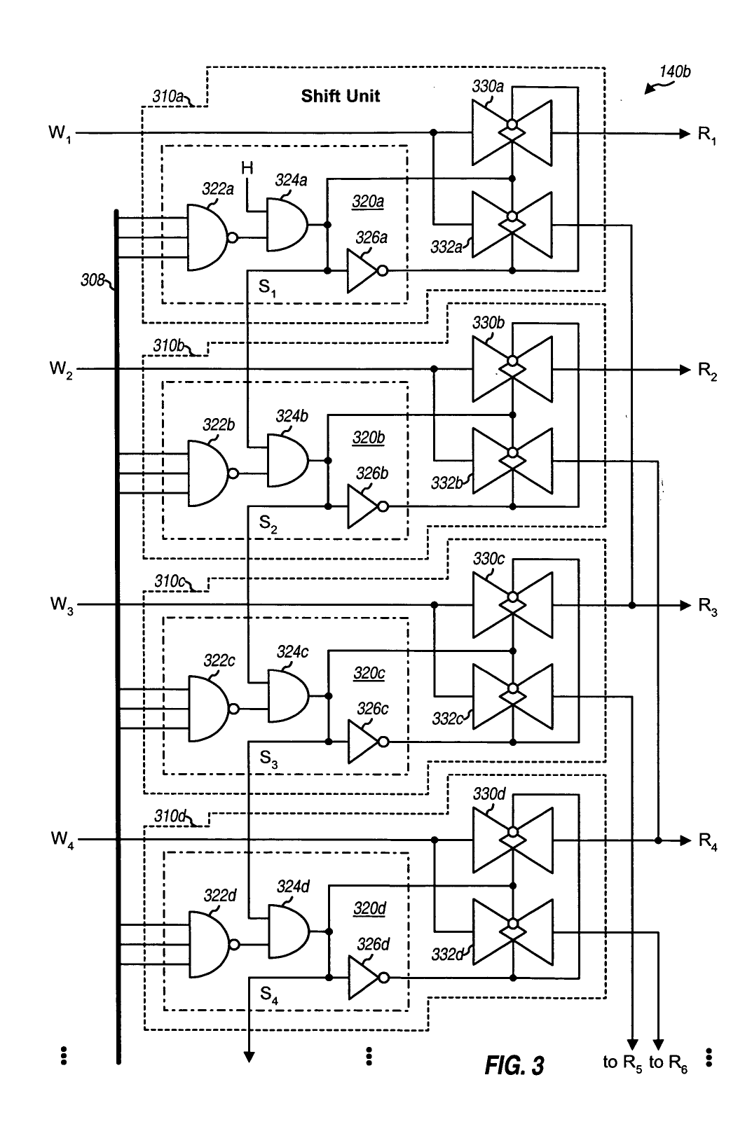

FIG. 3 shows a row shifter 140b, which is another embodiment of row shifter 140 within memory device 100 in FIG. 1. For this embodiment, L=2. Row shifter 140b includes N shift units 310 for the N word lines. Each shift unit 310 couples to one word line and further to two row lines that are separated by two rows. Thus, shift unit 310a couples to the first word line W₁ and to row lines R₁ and R₃, shift unit 310b couples to the second word line W₂ and to row lines R₂ and R₄, shift unit 310c couples to the third word line W₃ and to row lines R₃ and R₅, and so on, and the last shift unit (not shown in FIG. 3) couples to the last word line W_{N} and to row lines R_{N} and R_{N+2}.

Each shift unit 310 includes a shift control unit 320 and two switches 330 and 332. Within shift unit 310a for the first word line W, switch 330a has one end coupled to word line W₁ and the other end coupled to row line R₁, and switch 332a has one end coupled to word line W₁ and the other end coupled to row line R₃. Shift control unit 320a receives an indication as to whether row 1 is defective and generates a different control signal S₁ and \overline{S}₁ for switches 330a and 332a. Shift control unit 320a is described in detail below. If row 1 is not defective, then switch 330a is enabled and couples word line W₁ to row line R₁, and switch 332a is disabled. Conversely, if row 1 is defective, then switch 330a is disabled, and switch 332a is enabled and couples word line W₁ to row line R₃.

Within shift unit 310b for the second word line W₂, shift control unit 320b receives an indication as to whether row 2 is defective and the control signal S₁ from shift control unit 320a for the first word line W₁. Shift control unit 320b generates a differential control signal S₂ and \overline{S}₂ for switches 330b and 332b based on the two inputs. If row 2 is not defective and if word line W₁ has been coupled to row line R₁, then switch 330b is enabled and couples word line W₂ to row line R₂, and switch 332b is disabled. Conversely, if row 2 is defective or if word line W₁ has been coupled to row line R₃, then switch 330b is disabled, and switch 332b is enabled and couples word line W₂ to row line R₄.

Shift unit 310 for each of word lines W₃ through W_{N} is coupled in similar manner as shift unit 310b for word line W₂. For word lines W₃ through W_{N}, the shift unit for each word line W_{y} (where y ∈ {3, . . . , N}) couples word line W_{y} to row line R_{y} if regular row y is not defective and if word line W_{y-1} is not coupled to row line R_{y+1}. The shift unit couples word line W_{y} to row line R_{y+2} if regular row y is defective or if word line W_{y-1} is coupled to row line R_{y+1}.

Shift control unit 320 within each shift unit 310 includes a NAND gate 322, an AND gate 324, and an inverter 326. Shift control units 320 for all N shift units 310 are coupled in similar manner, except that AND gate 324a within shift control unit 320a for the first word line W₁ has one input coupled directly to logic high (“H”) instead of the control signal from the shift control unit for a preceding word line.

Within shift control unit 320b for the second word line W₂, the inputs of NAND gate 322b are coupled to a bus 308 that carries pre-decoded lines for an address of a defective row. For example, if memory array 150 includes 256 rows, then bus 308 may include 20 pre-decoded lines for a defective row address, as described above for row address pre-decoder 120 in FIG. 1. The three inputs of NAND gate 322b are coupled to three pre-decoded lines selected from among the 20 pre-decoded lines in bus 308. These three pre-decoded lines can be used to determine whether row 2 is defective. The output of NAND gate 322b is logic high if row 2 is non-defective and is logic low if row 2 is defective. AND gate 324b has one input coupled to the output of NAND gate 322b and another input receiving the control signal S₁ from shift control unit 320a for the first word line W₁. The output of AND gate 324b is logic low if either (1) row 2 is defective, which is indicated by the output of NAND gate 322b being at logic low, or (2) word line W₁ is coupled to row line R₃, which is indicated by the control signal S₁ being at logic low. Conversely, the output of AND gate 324b is logic high if both row 2 is non-defective and word line W₁ is coupled to row line R₁. AND gate 324b provides the control signal S₂, which is inverted by inverter 326b to generate the complementary control signal \overline{S}₂.

Shift control unit 320 for each of the other word lines is coupled and operated in a manner similar to shift control unit 320b for word line W₂. The inputs of NAND gate 322 for each word line are coupled to a different set of pre-decoded lines selected from among all of the pre-decoded lines in bus 308. Table 1 summarizes the outputs of NAND gate 322 and AND gate 324 within shift control unit 320 for word line Wₓ.

TABLE 1

| Gate | State | Condition |
|---|---|---|
| NAND gate | High | Regular row x is non-defective |
| output | Low | Regular row x is defective |
| AND gate | High | Regular row x is non-defective AND preceding |
| output | | word line Wₓ₋₁ is coupled to row line Rₓ₋₁ |
| | Low | Regular row x is defective OR preceding word line |
| | | Wₓ₋₁ is coupled to row line Rₓ₊₁ |

For the embodiment shown in FIG. 3, the information for a defective row is shifted down from row to row. This embodiment can efficiently fix a common type of failure in which two adjacent row lines are shorted together. The first defective row is detected, and the word line for this defective row is shifted down by two rows as described above. The row adjacent to the defective row is also automatically repaired, and the word line for this adjacent row is also shifted down by two rows. This embodiment can reduce the number of lines needed to convey the defective rows.

For the embodiment shown in FIG. 3, if a defective row is detected among the N regular rows, then the word line for that defective row and all subsequent word lines are shifted down by two rows. For example, a defective row 3 will result in (1) odd-numbered word lines W₃, W₅, W₇, and so on to be shifted down by two rows and coupled to odd-numbered row lines R₅, R₇, R₉, and so on and (2) even-numbered word lines W₄, W₆, W₈, and so on to be shifted down by two rows and coupled to even-numbered row lines R₆, R₈, R₁₀, and so on. The odd-numbered word lines are thus shifted down to odd-numbered row lines, and the even-numbered word lines are shifted down to even-numbered row lines. Row shifter 140b can repair up to two consecutive defective rows.

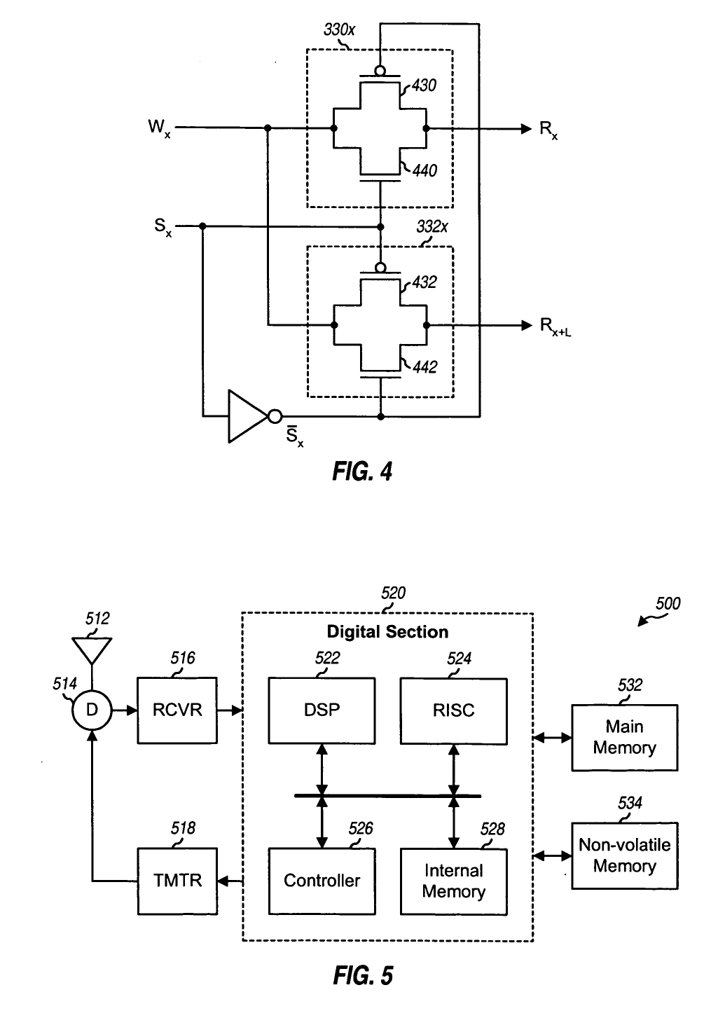

FIG. 4 shows a schematic diagram of switches 330x and 332x, which may be use for each pair of switches 230 and 232 in FIG. 2 and also for each pair of switches 330 and 332 in FIG. 3. For the embodiment shown in FIG. 4, switch 330x is implemented with an N-channel field effect transistor (N-FET) 430 and a P-channel FET (P-FET) 440 that are coupled in parallel. The sources of N-FET 430 and P-FET 440 are coupled together, and the drains of N-FET 430 and P-FET 440 are also coupled together. Switch 332x is implemented with an N-FET 432 and a P-FET 442 that are coupled in parallel so that their sources are coupled together and their drains are also coupled together. The gates of N-FET 440 and P-FET 432 receive the control signal Sₓ, and the gates of P-FET 430 and N-FET 442 receive the complementary control signal \overline{S}ₓ.

When the control signal Sₓ is at logic high, N-FET 440 is turned on by the logic high on the control signal Sₓ, and P-FET 430 is also turned on by the logic low on the complementary control signal \overline{S}ₓ. P-FET 432 is turned off by the logic high on the control signal Sₓ, and N-FET 442 is also turned off by the logic low on the complementary control signal \overline{S}ₓ. Word line Wₓ is then coupled to row line Rₓ when the control signal Sₓ is at logic high. Conversely, when the control signal Sₓ is at logic low, P-FET 432 is turned on by the logic low on the control signal Sₓ, and N-FET 442 is also turned on by the logic high on the complementary control signal \overline{S}ₓ. N-FET 440 is turned off by the logic low on the control signal Sₓ, and P-FET 430 is also turned off by the logic high on the complementary control signal \overline{S}ₓ. Word line Wₓ is thus coupled to row line R_{x+L} when the control signal Sₓ is at logic low.

FIG. 4 shows a specific embodiment of the switches using complementary metal oxide semiconductor (CMOS) transistors coupled as pass gates. The switches may also be implemented with other designs and other IC process technologies.

Row shifters 140a and 140b can provide various advantages. First, up to L adjacent defective rows may be repaired regardless of where these adjacent defective rows are located within the memory array, which can improve yield. Second, operating speed for the memory device is minimally degraded since the switches coupling the word lines to the row lines introduce only a small delay. Third, the row shifter is relatively simple in design.

The memory device described herein may be used for a stand-alone memory IC. The memory device may also be used for an embedded memory within an application specific integrated circuit (ASIC), a digital signal processor (DSP), a reduced instruction set computer (RISC), a digital signal processing device (DSPD), a programmable logic device (PLD), a field programmable gate array (FPGA), a processor, a controller, a micro-controller, a microprocessor, and so on. The memory device may also be used for various types of memories such as random access memory (RAM), static RAM (SRAM), dynamic RAM (DRAM), synchronous DRAM (SDRAM), video RAM (VRAM), synchronous graphic RAM (SGRAM), read only memory (ROM), Flash memory, and so. Different types of memories generally use different types of memory cells to store data.

The memory device described herein may be used for various applications such as communication, networking, computing, consumer electronics, and so on. The memory device may also be used in various electronics devices such as wireless communication devices, cellular phones, wireless PDAs, wireless modem modules, laptop computers, and other digital circuits that use memories. The use of the memory device for a wireless device is described below.

FIG. 5 shows a block diagram of a wireless device 500 that includes the memory device described herein. Wireless device 500 may be a cellular phone, a terminal, a handset, or some other apparatus. Wireless device 500 may be capable of communicating with a code division multiple access (CDMA) system, a time division multiple access (TDMA) system, a Global System for Mobile Communications (GSM) system, an Advanced Mobile Phone System (AMPS) system, Global Positioning System (GPS), a multiple-input multiple-output (MIMO) system, an orthogonal frequency division multiplexing (OFDM) system, an orthogonal frequency division multiple access (OFDMA) system, a wireless local area network (WLAN), and/or some other wireless communication systems and networks. A CDMA system may implement Wideband-CDMA (W-CDMA), cdma2000, or some other radio access technology. A WLAN may be an IEEE 802.11 network, a Bluetooth network, and so on.

Wireless device 500 provides bi-directional communication via a receive path and a transmit path. For the receive path, forward link signals transmitted by base stations are received by an antenna 512, routed through a duplexer (D) 514, and provided to a receiver unit (RCVR) 516. Receiver unit 516 conditions and digitizes the received signal and provides input samples to a digital section 520 for further processing. For the transmit path, a transmitter unit (TMTR) 518 receives from digital section 520 data to be transmitted, processes and conditions the data, and generates a reverse link signal, which is routed through duplexer 514 and transmitted via antenna 512 to the base stations.

Digital section 520 includes various processing units and support circuitry such as, for example, a DSP 522, a RISC 524, a controller 526, and an internal memory 528. DSP 522 and/or RISC 524 may implement (1) a modem processor that performs processing for data transmission and reception (e.g., encoding, modulation, demodulation, decoding, and so on), (2) a video processor that performs processing on still images, moving videos, moving texts, and so on, (3) a graphics processor that performs processing on graphics for video games, 3-D avatars, and so on, and/or (4) other processors for other applications. Internal memory 528 stores program codes and/or data used by the various units within digital section 520.

A main memory 532 provides mass storage for wireless device 500 and may be a RAM, an SRAM, a DRAM, an SDRAM, and so on. A non-volatile memory 534 provides non-volatile storage and may be a Flash memory, a ROM, and so on. The memory device described herein may be used for internal memory 528, main memory 532, and/or non-volatile memory 534. The memory device may also be used for embedded memories within DSP 522, RISC 524, and controller 526.

The memory device described herein may be fabricated in various IC process technologies such as CMOS, N-MOS, P-MOS, bipolar-CMOS (Bi-CMOS), and so on. CMOS technology can fabricate both N-FET and P-FET devices on the same die, whereas N-MOS technology can only fabricate N-FET devices and P-MOS technology can only fabricate P-FET devices. The memory device may be fabricated using any device size technology (e.g., 130 nanometer (run), 65 nm, 30 nm, and so on). The memory device described herein is generally more advantageous as IC process technology scales to smaller geometry and defects are more likely to be localized.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An integrated circuit comprising:
a plurality of rows of memory cells; and
a shift circuit operative to couple a plurality of word lines to the plurality of rows of memory cells, wherein the shift circuit is operative to couple each word line to either a designated row of memory cells or an alternate row of memory cells that is at least two rows away from the designated row of memory cells.

2. The integrated circuit claim 1, wherein the plurality of rows of memory cells comprise a plurality of regular rows of memory cells and at least two redundant rows of memory cells, and wherein each regular row of memory cells is a designated row of memory cells for one word line.

3. The integrated circuit claim 1, wherein the alternate row of memory cells for each word line is two rows away from the designated row of memory cells for the word line.

4. The integrated circuit claim 1, wherein the shift circuit is operative to couple even-numbered word lines to even-numbered rows of memory cells and to couple odd-numbered word lines to odd-numbered rows of memory cells.

5. The integrated circuit claim 1, wherein the shift circuit is operative to couple each word line to the designated row of memory cells if the designated row is non-defective and to couple the word line to the alternate row of memory cells if the designated row is defective.

6. The integrated circuit claim 5, wherein the shift circuit is further operative to couple each word line to the alternate row of memory cells if another word line is coupled to the designated row of memory cells.

7. The integrated circuit claim 5, wherein the shift circuit is further operative to couple each word line to the alternate row of memory cells if a preceding word line is coupled to an alternate row of memory cells for the preceding word line.

8. The integrated circuit claim 1, wherein the shift circuit is operative to detect for a defective row of memory cells and to couple the word line corresponding to the defective row of memory cells and subsequent word lines to alternate rows of memory cells.

9. The integrated circuit claim 1, wherein the shift circuit comprises a plurality of shift units, one shift unit for each word line, each shift unit comprising
a first switch operative to couple the word line to the designated row of memory cells, and
a second switch operative to couple the word line to the alternate row of memory cells.

10. The integrated circuit claim 9, wherein each shift unit further comprises a control unit operative to receive an indication of whether the designated row of memory cells is defective and to generate a control signal to enable either the first switch or the second switch.

11. The integrated circuit claim 10, wherein the control unit for each shift unit is further operative to receive a control signal for a preceding word line and to generate the control signal for the first and second switches further based on the control signal for the preceding word line.

12. The integrated circuit claim 10, wherein the control unit for each shift unit is further operative to receive a set of pre-decoded lines for an address of a defective row of memory cells and to determine whether the designated row of memory cells is defective based on the set of pre-decoded lines.

13. The integrated circuit claim 9, wherein the first and second switches are each formed with an N-channel field effect transistor (N-FET) and a P-channel FET (P-FET) coupled in parallel.

14. The integrated circuit claim 1, wherein the plurality of rows of memory cells are for a random access memory (RAM), a static RAM (SRAM), a dynamic RAM (DRAM), or a Flash memory.

15. An integrated circuit comprising:
a plurality of rows of memory cells comprised of a plurality of regular rows of memory cells and at least two redundant rows of memory cells; and
a shift circuit operative to couple a plurality of word lines to the plurality of rows of memory cells, wherein each regular row of memory cells is a designated row of memory cells for one word line, and wherein the shift circuit is operative to couple each word line to either the designated row of memory cells for the word line or an alternate row of memory cells that is two rows away from the designated row of memory cells.

16. The integrated circuit claim 15, wherein each even-numbered word line is associated with an even-numbered designated row of memory cells and an even-numbered alternate row of memory cells that is two rows away, and wherein each odd-numbered word line is associated with an odd-numbered designated row of memory cells and an odd-numbered alternate row of memory cells that is two rows away.

17. The integrated circuit claim 15, wherein the shift circuit is operative to couple each word line to the designated row of memory cells if the designated row is non-defective and to couple the word line to the alternate row of memory cells if the designated row is defective.

18. The integrated circuit claim 17, wherein the shift circuit is further operative to couple each word line to the alternate row of memory cells for the word line if an immediately preceding word line is coupled to the alternate row of memory cells for the immediately preceding word line.

19. The integrated circuit claim 15, wherein the shift circuit is operative to detect for a defective row of memory cells and to couple the word line corresponding to the defective row of memory cells and subsequent word lines to alternate rows of memory cells.

20. An electronics device comprising:
a processor operative to perform processing for the electronics device; and
a memory device comprising
a plurality of rows of memory cells, and
a shift circuit operative to couple a plurality of word lines to the plurality of rows of memory cells, wherein the shift circuit is operative to couple each word line to either a designated row of memory cells or an alternate row of memory cells that is at least two rows away from the designated row of memory cells.

21. The electronics device claim 20, wherein the processor and the memory device are fabricated on a single integrated circuit.
